(19) United States
(12) Patent Application Publication
(10) Pub. No.: US 2011/0148376 A1
(43) Pub. Date: Jun. 23, 2011

(54) MOSFET WITH GATE PULL-DOWN

(75) Inventors: Shuming Xu, Schnecksville, PA (US); Jacek Korec, Sunrise, FL (US); Osvaldo J. Lopez, Annandale, NJ (US)

(73) Assignee: Texas Instruments Incorporated, Dallas, TX (US)

(21) Appl. No.: 12/964,484

(22) Filed: Dec. 9, 2010

Related U.S. Application Data
(60) Provisional application No. 61/289,551, filed on Dec. 23, 2009.

(51) Int. Cl. G05F 1/00; H03K 17/687

(52) U.S. Cl. 323/282; 327/434

(57) ABSTRACT

A MOSFET main switch transistor has a pull-down FET coupled between a drain thereof and the gate of the main switch transistor. A gate of the pull-down FET is coupled to the drain of the main switch transistor by a capacitor and is connected to a source thereof by a resistor. The pull-down FET is operated by capacitive coupling to the voltage drop across the main switch and can be used to hold the gate of the main switch transistor at or near its source potential to avoid or reduce unintentional turn-on of the main switch transistor by the Miller effect.

### CROSS-REFERENCE TO RELATED APPLICATIONS

This application is a nonprovisional of U.S. Provisional Application Ser. No. 61/289,551, filed Dec. 23, 2009 and is related to commonly-owned, co-pending application Ser. No. ______ (TI-67872), entitled “Integration of MOSFETS in a Source-Down Configuration,” filed on even date, which is a nonprovisional of U.S. Provisional Application Ser. No. 61/289,516, the contents of which are incorporated herein by reference in its entirety.

### FIELD OF THE INVENTION

The present invention relates to a MOSFET in which bouncing of the gate bias leading to unintentional turn-on of the device is limited or eliminated, and in particular to such a device in a push-pull stage of a converter operating in a switching mode.

### BACKGROUND OF THE INVENTION

Switching mode DC to DC converters are commonly used to provide conversion from one DC voltage to another at high efficiency. Improving the efficiency of such converters is an important design goal, especially where large banks of such converters are operating within the same space, such as in computer server farms. In these situations, the improvement in the efficiency of the converter not only reduces the amount of power the converter consumes, but dramatically reduces the cooling load placed upon the premises.

Methods to improve the efficiency of switching type DC to DC converters have been extensively studied. In an article entitled “The future of Discrete Power in VRM Solutions,” at the Intel Technology Symposium 2003, Jon Hancock describes the advantages that can be achieved by increasing the switching frequency, but this is limited by the switching losses of the power switches. One source of switching losses is the shoot-through current that occurs when the low-side switch is turned back on during the conduction period of the high-side switch which is caused by bouncing of the gate electrode bias of the low-side switch. He describes the components that require special attention to minimize the parasitic inductance component to reduce the dv/dt on the drain of the low-side switch MOSFET. A high dv/dt on the drain of the transistor injects charge into the gate of the low-side switching transistor via the Miller effect “Cgd”. This injected charge has to be accommodated by the Cgs capacitance before it is drained to ground through the opposite stage of the gate driver. This event is associated with a short term increase in Vgs at the gate of the switching transistor. If the amplitude of the Vgs increase is higher than the threshold voltage Vth of the MOSFET, then the switch is turned on and the large shoot-through current flows from supply rail to ground. This effect has to be avoided as it leads to significant power loss, and if repetitive, will impair the reliability of the system.

In an article entitled “DV/DT Immunity Improved Synchronous Buck Converters,” in Power Electronics Technology, July 2005, Steve Mappus describes this problem. One solution is to utilize transistors that have a higher Vth, but such transistors usually have a higher Rds,on which leads to higher conduction losses. He then goes on to describe gate driver selection. Large charge and sink currents have to be delivered by the gate drivers in order to enable fast switching of the MOSFETs. Here, not only the output of the gate driver is important, but the gate resistance and source inductance of the MOSFET have to be kept at a minimum in order to allow hard switching.

If the break-before-make delay time of the switching of the high-side and low-side transistors is long enough, there is a time period where the integral diode of the lower transistor switch conducts the free wheeling current. At the end of the delay time, the diode is commutated by the changing polarity of the voltage at the switch node and the associated reverse recovery current peak adds to the nominal current increasing switching power loss. Any power loss decreases the efficiency of the power conversion and high switching loss inhibits the aimed increase in the switching frequency.

The shoot-through problem in synchronous buck converters has also been addressed in Fairchild Semiconductor Application No. AN-6003, Apr. 25, 2003. A solution proposed here is the utilization of slowing the rise time on the high-side switching transistor. This, of course, reduces the switching efficiency of the high-side switch.

In the U.S. Pat. No. 5,744,994, issued Apr. 20, 1998, to Richard K. Williams, he describes the current flowing through the lower switching transistor under forward bias of the integral PN diode as being shared by the integral diode and the FET channel. The lower the Vth of the MOSFET, the more current flows through the channel and the charge stored in the body diode “Qrr” is less. Less Qrr means lower reverse recovery current peak and lower power loss during computation. Also, the design of the lower switching transistor device with a low Vth lowers its Rds,on value at a given drive in Vgs voltage. This in turn lowers the conduction loss in the lower switch and increases the overall converter efficiency. However, this exacerbates the shoot-through problem as discussed above.

Accordingly, there is a need to implement a power MOSFET switch with a low threshold voltage with reduced or no unintentional current flow due to a Miller effect during turn-off event.

### SUMMARY OF THE INVENTION

It is a general object of the present invention to utilize a capacitive coupling between the gate and drain terminals of a power MOSFET, which is the root of the problem of unintentional turn-on of the switch, as a solution to the problem. This and other objects and features are attained in accordance with an aspect of the invention by a MOSFET device comprising a main power MOSFET having a drain, source and gate. A pull-down MOSFET has a drain connected to the gate of the main power MOSFET and a source connected to the source of the main power MOSFET. A gate of the pull-down MOSFET is connected to one terminal of a capacitor and another terminal of the capacitor is connected to the drain of the main power MOSFET, whereby dv/dt of a potential at the drain of the main power MOSFET during turn-off of the main power MOSFET causes the pull-down MOSFET to turn-on via capacitive coupling and hold the gate of the main power MOSFET during turn-off.

Another aspect of the invention includes a switching DC to DC converter with a push-pull stage having a high-side switch and a low-side switch, the low-side switch comprising a main power MOSFET having a drain, source and gate. A pull-down MOSFET has a drain connected to the gate of the main power MOSFET and a source connected to the source of the main power MOSFET. A gate of the pull-down MOSFET is connected to one terminal of a capacitor, another terminal of the capacitor is connected to the drain of the main power MOSFET, whereby dv/dt of a signal at the drain of the main power MOSFET during turn-off of the main power MOSFET causes the pull-down MOSFET to turn-on via capacitive coupling and hold the gate of the main power MOSFET at or near source potential to prevent turn-on of the main power MOSFET during turn-off.

Another aspect of the invention is provided by a method of operating a switching DC to DC converter comprising alternately turning on and off a high-side MOSFET switch and a low-side switch. When turning the low-side MOSFET switch off, utilizing the Miller effect voltage on a gate of a pull-down MOSFET to operate the pull-down MOSFET to couple a gate of the low-side MOSFET switch to a source thereof, whereby conduction in the low-side MOSFET switch during turn-off is reduced or prevented.

Yet another aspect of the invention includes a high-side switch with a main power MOSFET incorporating a pull-down FET. A pull-down MOSET has a drain connected to the gate of the main power MOSFET and a source connected to the source of the main power MOSFET. A gate of the pull-down MOSFET is connected to one terminal of a capacitor, another terminal of the capacitor is connected to the drain of the main power MOSFET, whereby dv/dt of a signal at the drain of the main power MOSFET during turn-off of the main power MOSFET causes the pull-down MOSFET to turn-on via capacitive coupling and speed-up the turn-off of the main power MOSFET. The hard turn-off of the high-side switch reduces the switching losses associated with this transistor.

### BRIEF DESCRIPTION OF THE DRAWINGS

FIG. 1 is a schematic diagram showing one embodiment of a low-side switch according to the present invention;

FIG. 2 shows the layout of the present invention in accordance with a related application;

FIG. 3 shows a switching stage for a switched mode power supply in accordance with the present invention;

FIGS. 4-6 show Vds and Vgs waveforms obtained in a PSPICE simulation of the present invention;

FIG. 7 shows the calculated efficiency for a synchronous buck converter;

FIG. 8 shows the application of pull-down FETs for both the low-side and the high-side switches; and

FIGS. 9-11 show the impact of lowering the sink current capability of the gate drivers.

### DETAILED DESCRIPTION

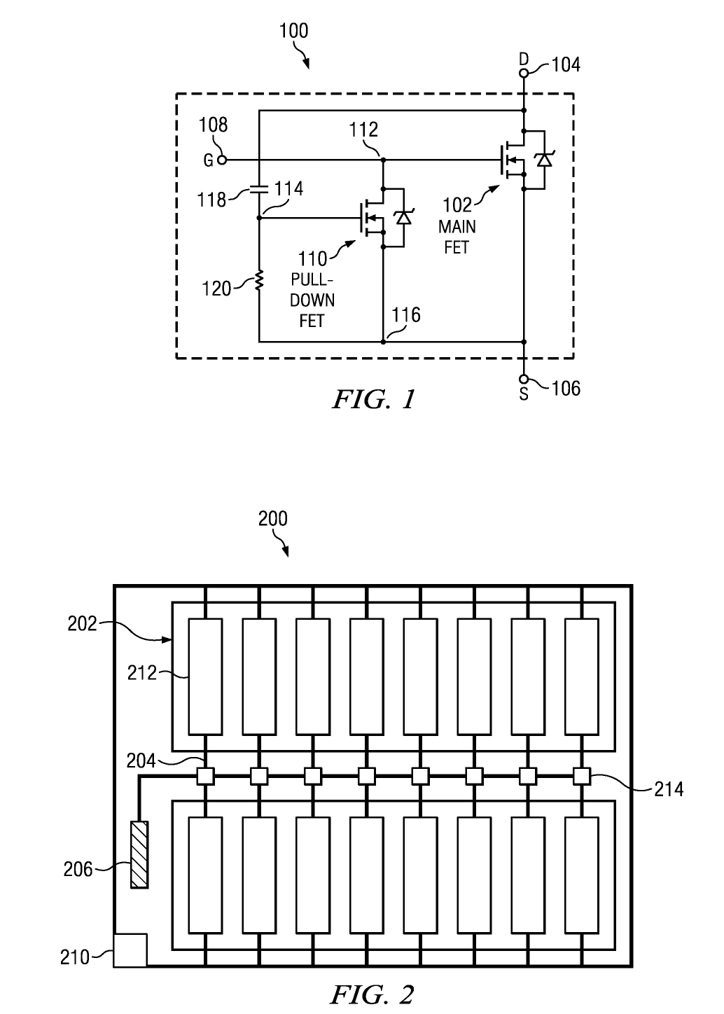

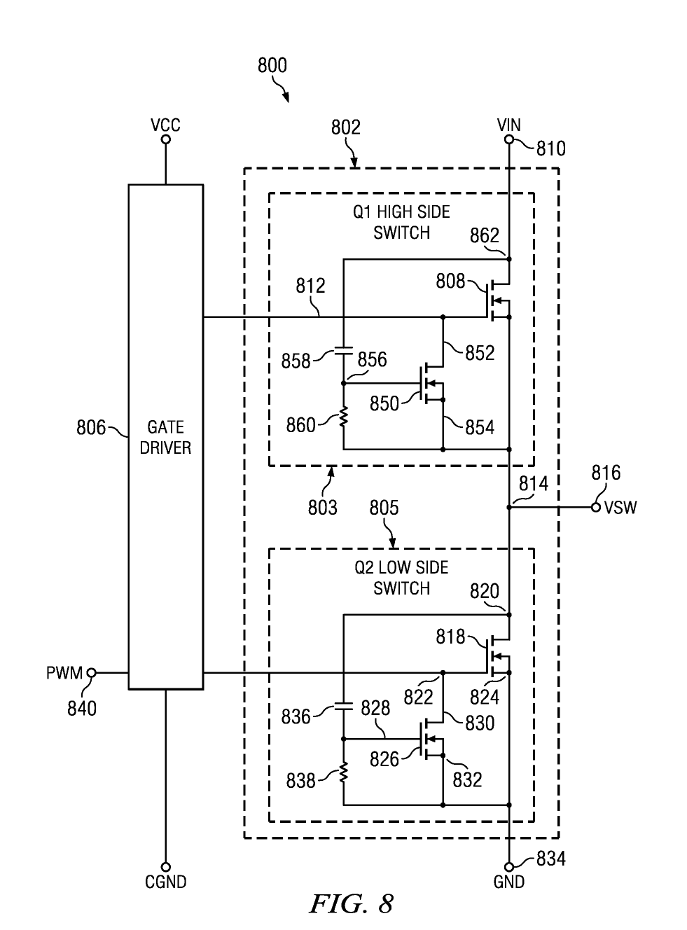

An embodiment of the present invention is shown in FIG. 1, generally as 100. Although this embodiment as shown and discussed is for a low-side switch for a synchronous buck converter, the invention is not so limited, and an embodiment in which the invention is utilized in both the low-side and high-side switches will be discussed later in connection with FIG. 8. As easily recognized by people skilled in the art, the embodiment shown in FIG. 1, can be implemented at any switching power MOSFET, and especially can be implemented at MOSFETs used in push-pull configuration in any switched DC/DC converter topology. Also, the solution using a capacitive coupling to turn-on the pull-down transistor can be implemented in lateral power MOSFETs used in IC's designed for power management applications.

As shown in FIG. 1, the main FET, which as shown, is a NMOS transistor, has a drain 104, a source 106 and a gate 108. A second FET, the pull-down FET 110, is connected so that its drain is connected to the gate of transistor 102 at 112. The source of transistor 110 is connected to the source of transistor 102 at 116. A capacitor 118 is connected between the drain 104 of transistor 102 and the gate 114 of transistor 110. A resistor 120 is connected to the gate 114 of transistor 110. The resistor 120 is also connected to the source of transistor 110 at 116, which is, in turn, connected the source of main FET 102 at 106.

In this embodiment, pull-down FET is a NMOS transistor which has an active area in the range of 0.5 to 4 percent of the activate area of the main NMOS transistor 102. In one embodiment, the coupling capacitor has a value in the range of 0.5 to 3 percent of the Cgs of the pull-down MOSFET and the resistor 120 has a value between 100 and 10 k ohms. The optional resistor 120 is attached between the gate and source terminal MOSFET 110 to stabilize the start up of the circuit and provides a reset function after the turn-on of the pull-down MOSFET.

In operation during the conduction of the main MOSFET 102, the pull-down MOSFET 110 is turned off and does not play a role. During the turn-off of the main switch MOSFET 102, the dv/dt effect across the main switch during the turn-off process, causes the coupling capacitor to pull up the gate of the pull-down MOSFET 110, turning the transistor 110 on which, in turn, holds the gate terminal 108 of the main MOSFET 102 at its source potential. The self-driven pull-down MOSFET 110 speeds up the switching of the main MOSFET during turn-off, and eliminates or dramatically reduces the unintentional bouncing at its gate terminal 108. Thus, the Miller effect, which causes the problem at the gate 108 of the main MOSFET 102, is utilized to drive the pull-down MOSFET 110 and eliminate or drastically reduce the problem. Thus, the Miller effect, which causes the problem, becomes the solution to the problem.

In an embodiment, the pull-down FET 110 can be made on a small die with an integrated coupled capacitor 118 and the resistor 120. This die can be attached to the main switch and placed into the same housing which provides the user with a three-terminal device as in the case of a conventional MOSFET. However, the pull-down FET 110 can also be supplied outside the device or can be integrated into the same die containing the main MOSFET 102.

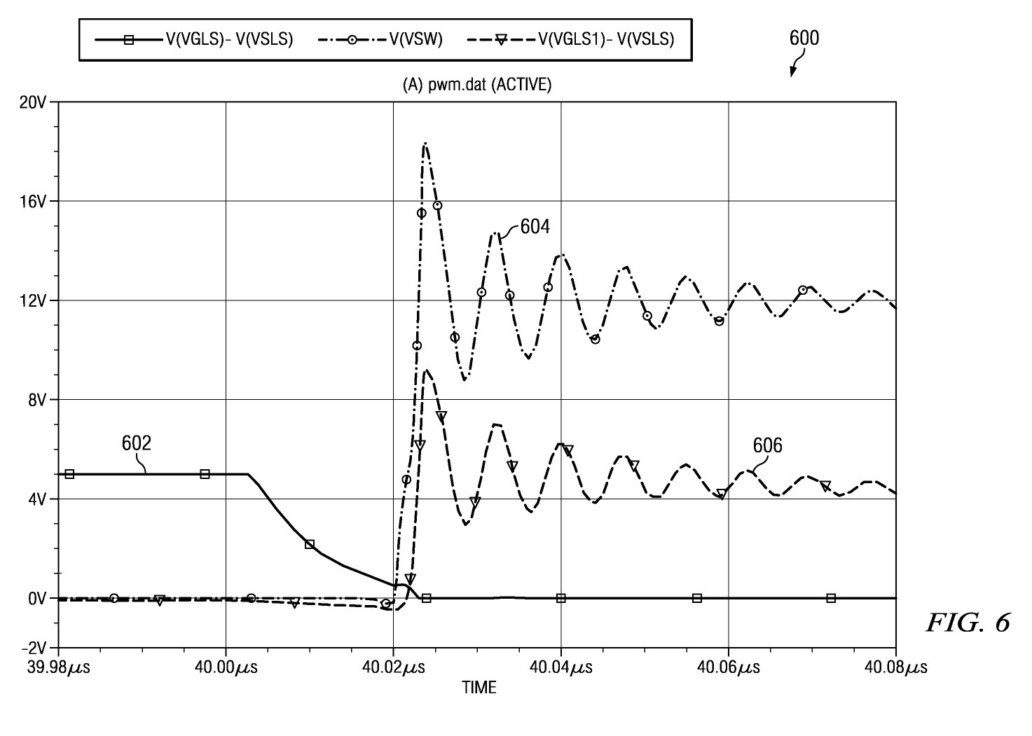

One way to realize all of the components integrated onto the same die is shown in FIG. 2. FIG. 2 shows the schematic of an integrated device in accordance with the teaching of the above-mentioned related application Ser. No. ______ (T67872), which has been incorporated herein by reference in its entirety. FIG. 2 is similar to FIG. 6 in that application.

In FIG. 2, this device is shown generally as 200. The drain terminal of the power FET is shown at 202 and the drain terminal of the pull-down FET, which is attached to the gate of the power FET, is shown at 204. The gate terminal of the pull-down FET with an integrated resistor is shown at 206 and the gate terminal of the power FET is shown at 210. The segments of the main power FET are shown at 212 and the segments of the pull-down FET are shown at 214.

In this embodiment, the pull-down FET is distributed across the active area of the main switch. The segments of the pull-down FET are attached to individual segments of the main FET, breaking the gate fingers in the middle. This layout assures minimum impact of the gate resistance on the switching speed of the combined transistors. The placing of the pull-down FET and the main switch FET on the same substrate in a common source technology, as taught in the co-pending application, assures a virtually zero inductance between their source terminals. The coupling capacitance can be easily integrated as insulator and metal layers running on top of the drain region of the main FET. This layout facilitates the utilization of the Miller effect to couple the pull-down FET gate and hold the pull-down FET at the source potential to eliminate or drastically reduce the shoot-through at the main switch, by placing both devices on the same die.

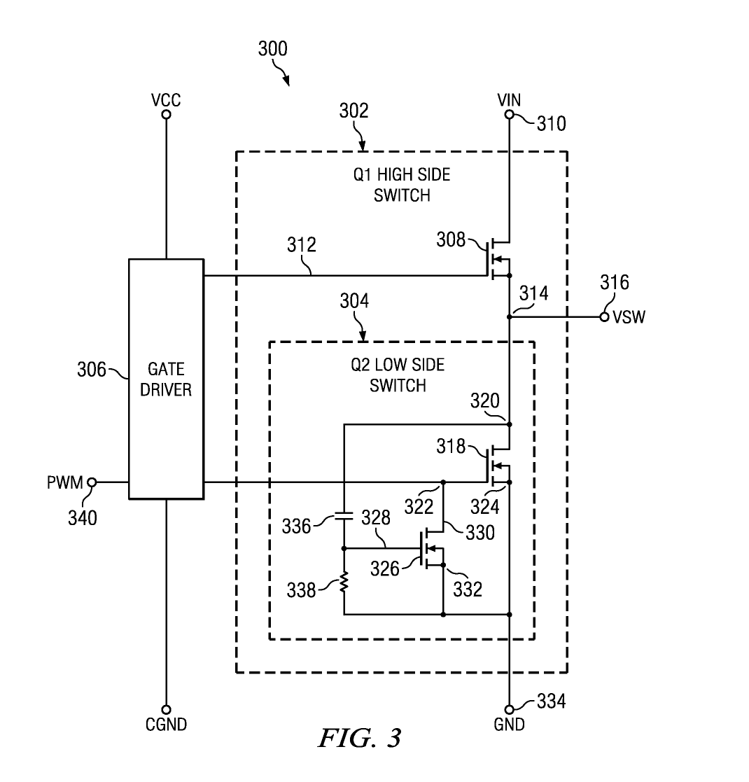

Another embodiment of the present invention is shown in FIG. 3, generally as 300. In this circuit, the high-side switch Q1 and the low-side switch Q2 are placed in the same housing to build a power block module 302. The high-side switch Q1 (308) has a drain 310, a gate 312 and a source 314 coupled to the output VSW 316. The low-side switch Q2 is a module 304, having main MOSFET switch 318 and pull-down MOSFET 326 contained therein. This module 304 can be built as described above in connection with FIGS. 1 and 2 by either being a module containing multiple die or being built with the teaching shown in FIG. 2. The module 304 has transistor 318 having a drain 320 connected to the source 314 and the output 316. The gate 322 of transistor 318 is connected to the gate driver circuit 306 and to the drain 330 of the pull-down MOSFET 326. Source 332 of MOSFET 326 is connected to the source 334 of main MOSFET switch 318. A capacitor 326 is coupled between the gate 328 of pull-down MOSFET 326 and the drain 320 of main MOSFET switch 318. Optional resistor 338 is connected between the gate 328 and the source 332 of pull-down MOSFET 326.

A gate driver circuit 306 is coupled between supply voltage VCC and ground CGND and provides the signals to the high-side and low-side switches, as well-known in the art. The gate driver circuit is triggered by a source of pulse width modulation signals PWM coupled terminal 340. The gate driver 306 provides the signals to the main switches at the gate 312 of the high-side switch and the gate 322 of the low-side switch transistors.

The implementation of such a module in a synchronous buck converter topology achieves following advantages. The low-side switch Q2 can be designed as a device with a low threshold voltage Vth. This lowers the Rds,on of the power switch for a given Vgs driving voltage. In turn, the low Vth reduces the Qrr of the integral body diode lowering switching losses. Having the integrated pull-down transistor 326 leads to a hard turn-off of the low-side switch Q2 that holds the gate thereof firmly at the source potential. This reduces switching power loss as well as drastically reducing or completely eliminating shoot-through events. This also increases the reliability of the circuit. The improved Rds,on and the switching components of the low-side switch Q2 lead to a higher efficiency for the converter.

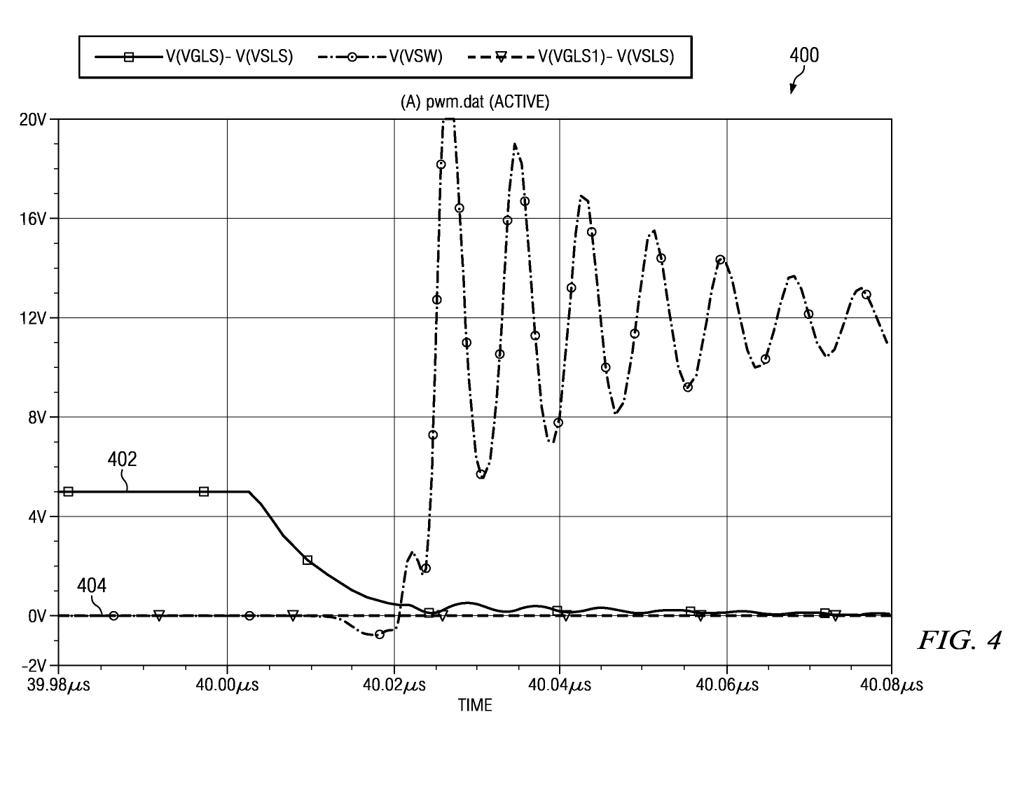

These advantages are illustrated by the PSPICE simulations which are shown in FIGS. 4-7. The assumptions made for these simulations are as follows: for the gate driver, the charge and sink capability of the high-side and low-side output stages of the gate driver are assumed to be equal and provide 2.5 amps at Vgs equal to VCC which is equal to 5 volts. For the power switches: the active area of the high-side switch is 3 mm2. The active area of the low-side switch is 8 mm2 and the active area of the pull-down FET is 0.08 mm2. The coupling capacitor (336 in FIG. 3) is 15 pF and the reset resistor (338 in FIG. 3) 1 k ohm. The threshold voltage Vth of the high-side switch is 1.6 volts and the threshold voltage for the low-side switch and the pull-down transistor FET is 1.4, 1.1 or 0.8 volts in the various graphs. The gate resistance for the high-side and the low-side switches, including the printed circuit board routing is 2 ohms and the gate inductance for the high-side and low-side switches is 1.5 nH. It is assumed that the power block module uses thick aluminum wires for the current handling connections so that a small package inductance of 0.1 to 0.3 nH exists. The input voltage was chosen to be 12 volts, and the output voltage was chosen to be 1.2 volts. The switching frequency was chosen at 1 MHz and the output inductance Lo was equal to 0.3 micro H. The DCR_Lo equals 1 m ohm and the delay time between the low-side and high-side switch pulse width modulation is 15 ns.

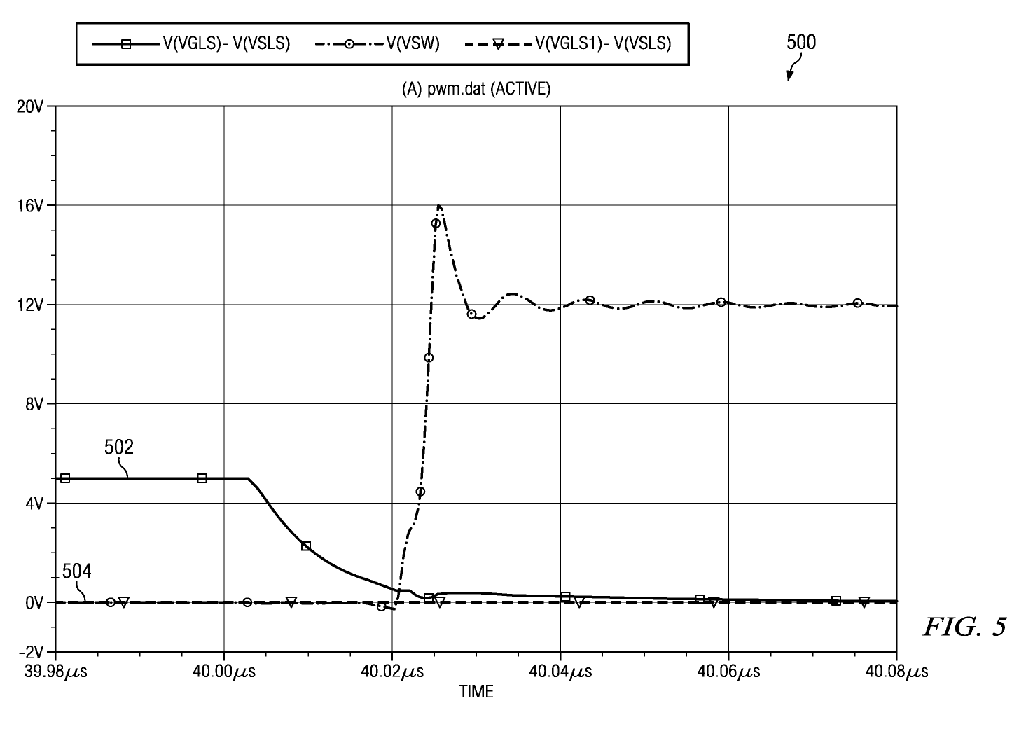

In FIGS. 4 and 5, the graphs 400, 500 show Vds 402, 502 and Vgs 404, 504 wave forms at the low-side switch for the referenced case where conventional switches without the pull-down FET are used. In FIG. 4, the simulation results for the low-side switch where the high threshold voltage of 1.4 volts shows that there is no shoot-through occurring and the ringing of the switch node is very high. In FIG. 5, a low-side switch having a low-threshold voltage of 0.8 volts shows a significant shoot-through occurring, dampening the ringing significantly. This dampening of the voltage ringing may look good, but is correlated with a very high power loss during shoot-through, so that the efficiency of the converter is low. Shoot-through also reduces the reliability of the converter.

FIG. 6 shows the simulation results for the case in which the low-side switch has a low threshold of 0.8 volts and has the integrated pull-down FET, generally as 600. The voltage Vds is shown as 602 and the voltage Vgs, for the low-side switch, is shown as 604. The graph 606 is the voltage between the gate of the pull-down FET and its source terminal. When compared with FIG. 4, the low threshold voltage increases the channel contribution to the current in the main MOSFET, operating as a synchronous rectifier. The conduction and Qrr of the integral body diode is less, increasing the efficiency of the converter. It can be noticed that in FIG. 6, as soon as the high-side switch is turned on, inducing a high dv/dt across the low-side switch, the pull-down FET is turned on, speeding up the remaining part of the commutation. The ringing of the switch node is slightly reduced due to a small cross current through the high-side and low-side switches at the onset of the turn-on of the high-side switch. This current corresponds to a leak in the LC resident circuit lowering its Q factor.

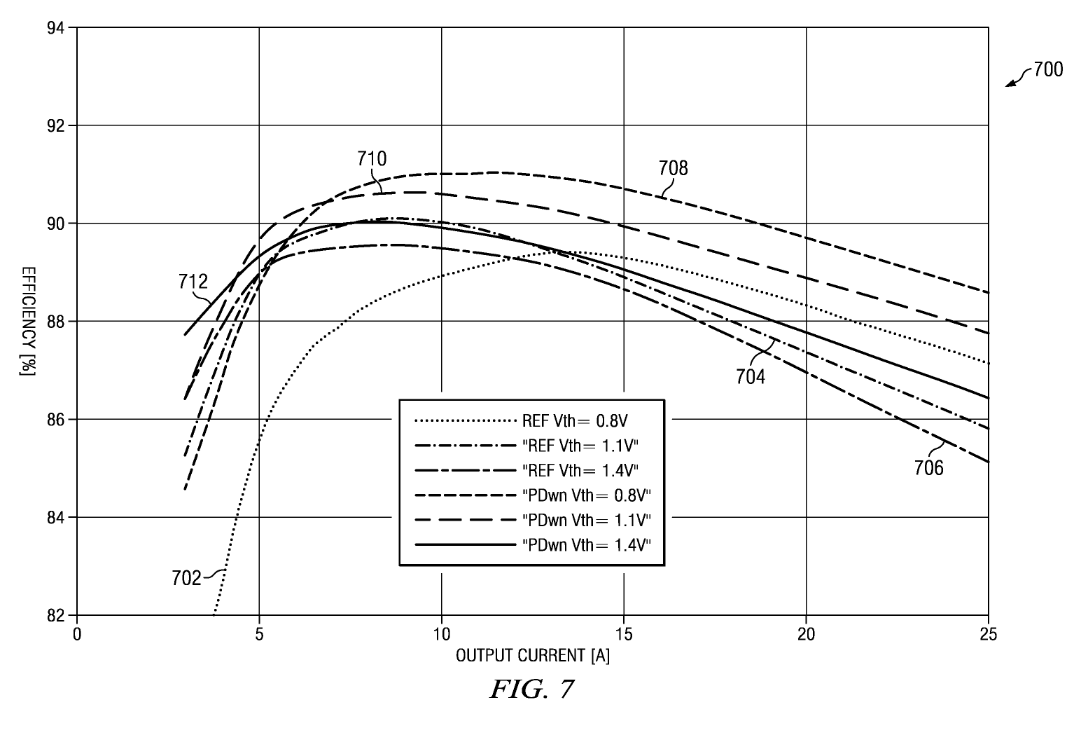

The efficiency of a converter for different cases under study is presented in FIG. 7, generally as 700, as a function of load current. The lines 702, 704 and 706, show the efficiency calculated for the low-side switch without the aid of the pull-down FET with three different voltage threshold cases, 0.8 volts, 1.1 volts and 1.4 volts, respectively. The intermediate threshold voltage of 1.1 volts (Graph 704), shows some efficiency advantage at full load due to the reduced Rds,on of the low-side switch. There is no significant penalty at light load as the low-side switch operates just at the onset of the shoot-through in this case. In contrast, as a threshold voltage is lowered to 0.8 volts (Graph 702), a strong shoot-through event is induced dramatically, lowering the efficiency of the converter at medium and light load conditions.

All three curves 708, 710 and 712 for the cases in which the low-side switch has the integrated pull-down FET, shows some advantages in efficiency as compared to the respective conventional case. This is due to the lower switching losses resulting from a harder turn-off of the low-side switch. Additionally, even in the case of the lowest threshold voltage of 0.8 volts (Graph 708), there is no sign of any shoot-through event. Some small decrease of efficiency with a low threshold voltage and light load conditions is due to a leakage current through the channel of the low-side main MOSFET switch during switching.

FIG. 8 illustrates a further embodiment of the present invention in which the pull-down FETs are integrated for both the low-side and the high-side switches in the power block module. This embodiment is similar to the embodiment of FIG. 3, except that a pull-down FET is also included for the high-side switch. Accordingly, similar reference numerals have been used to the reference numerals in FIG. 3.

FIG. 8 shows a module 802 comprising module 803 and 805 comprising main switching transistors 808, 818, respectively, and FET pull-down transistors 850, 830, respectively. The main switching MOSFET transistor 808 has its drain 862 coupled to a source of voltage VIN 810 and its source coupled to the node 814 between the modules 803 and 805. Node 814 is coupled to the output terminal VSW 816. The gate 812 of main switch MOSFET 808 is connected to a gate driver circuit 806, which is known in the art. A gate driver circuit provides the drive signals for the high-side switch Q1 and the low-side switch Q2. The gate 812 of main switch MOSFET 808 is also connected to the drain 852 of pull-down FET 850, which has its source 854 connected to the source of transistor 808 at 814. A capacitor 858 is connected between the drain 862 of main switch MOSFET 808 and the gate 856 of pull-down FET 850. The gate 856 of pull-down FET 850 is also coupled via reset resistor 860 to the source 854 of pull-down FET 850, which is in turn, coupled to the node 814.

The low-side switch Q2 has a main switch MOSFET 818, having its drain 820 connected to the node 814, and thus the output 816. The gate 822 is connected to gate driver 806 to receive gate drive signals as is known in the art. The source 824 of main switch MOSFET 818 is connected to ground at terminal 834. The FET pull-down transistor 830 has its drain 828 connected to gate 822 of main switch MOSFET 818. The gate 826 of pull-down FET 830 is coupled via capacitor 836 to the drain 820 of main switch MOSFET 818. The gate 826 of pull-down FET 826 is also coupled via reset resistor 838 to the source of pull-down FET 832 and the source 824 of the main switch MOSFET 818.

The gate driver 806 is connected to a supply voltage VCC and ground VCGND and receives a PWM (Pulse Width Modulation) signal at terminal 840. Gate driver circuit generates the switching wave forms for the high-side and the low-side switch as known in the art, and need not be described in detail here. An advantage of having a pull-down FET for the high-side main MOSFET switch is that it provides a sharp turn-off of the high-side main switch, which cuts switching losses. It allows the use of transistors with a low threshold Vth and can possibly cut the dead time between the operation of the high-side main MOSFET switch and the low-side main MOSFET switch at the fall edge of the duty cycle.

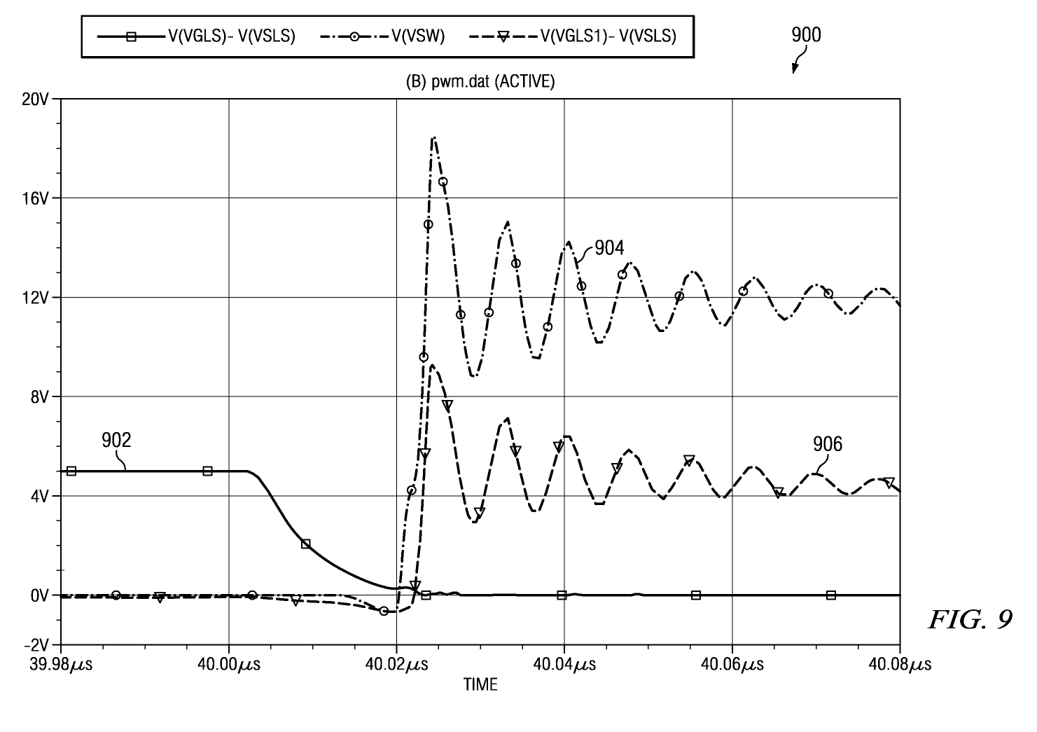

FIGS. 9-11 illustrate the impact of lowering the sink current capability of the gate drivers, generally at 900, 1000 and 1100. In all cases, the charge current capability for both, charge and sink MOSFETs is kept constant at 2.5 amps and the size of the sink MOSFET in the output driver stage is kept equal for the high-side and the low-side drivers. Similar to FIG. 6, the graphs 902 and 1002 represent Vds for the main switch MOSFET, 904 and 1004, represent Vgs for the main switch MOSFET and 906 and 1006 represent Vgs for the pull-down FET, respectively.

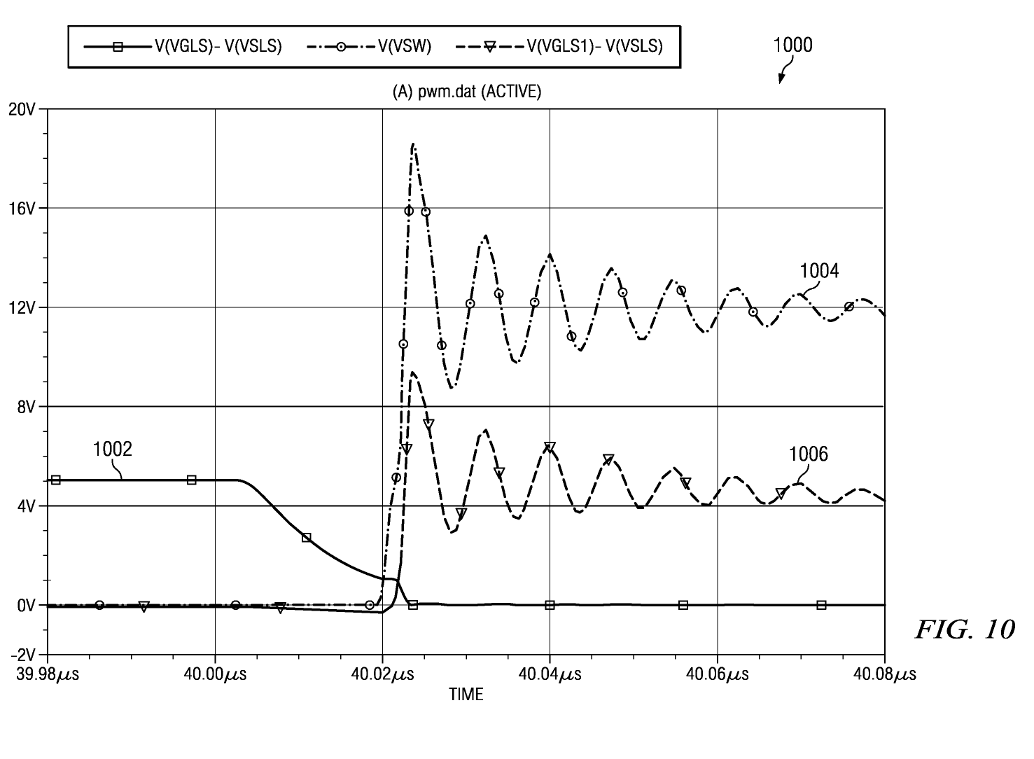

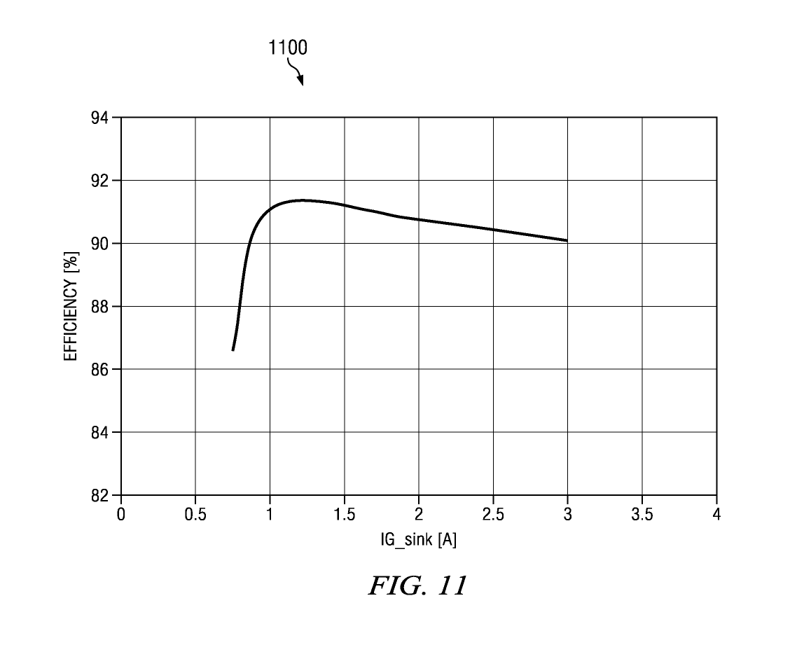

FIGS. 9 and 10 show the impact of lowering the sink current capability from 2.5 amps to 1 amp. The dropping Vgs voltage at the low-side switch is slower, providing enough low-side switch FET conduction at the onset of the turn-on of the high-side switch. Thus, the body diode conduction and the correlated Qrr effect are eliminated. This results in a higher efficiency of the converter as illustrated in FIG. 11, at graph 1100. However, if the sink current capability is below 1 amp, the Vgs of the low-side switch is still too high at the turn-on of the high-side switch and an excess cross current occurs. As a result, the efficiency of the converter drops very fast, with further lowering of the sink current capability.

Although the present invention has been described in detail, it should be understood that various changes, substitutions and alterations can be made thereto without departing from the spirit and scope of the invention as defined by the appended claims. For example, the present invention can be advantageously manufactured in accordance with the teachings of U.S. Pat. No. 7,282,765 to reduce the gate drive requirement, which is incorporated herein in its entirety by reference.

1. A MOSFET device comprising:
a main power MOSFET having a drain, source and gate;
a pull-down MOSFET having a drain connected to the gate of the main power MOSFET and a source connected to the source of the main power MOSFET, a gate of the pull-down MOSFET being connected to one terminal of a capacitor, another terminal of the capacitor being connected to the drain of the main power MOSFET, whereby dv/dt of a voltage bias at the drain of the main power MOSFET during turn-off of the main power MOSFET causes the pull-down MOSFET to turn-on and hold the gate of the main power MOSFET at or near source potential to prevent turn-on of the main power MOSFET during turn-off.

2. The MOSFET device of claim 1 wherein the main power MOSFET and the pull-down MOSFET are NMOSFETs.

3. The MOSFET device of claim 1 wherein the pull-down MOSFET has an active area of substantially 0.5 to 4.0 percent of the active area of the main power MOSFET.

4. The MOSFET device of claim 1 further comprising a resistor connected between the gate of the pull-down MOSFET and the source thereof.

5. The MOSFET device of claim 2 further comprising a resistor connected between the gate of the pull-down MOSFET and the source thereof.

6. The MOSFET device of claim 3 further comprising a resistor connected between the gate of the pull-down MOSFET and the source thereof.

7. The MOSFET device of claim 4 wherein the resistor value is substantially between 100 and 10,000 ohms.

8. The MOSFET device of claim 1 wherein the capacitor has a value of substantially 50 and 150 percent of the Cgs of the pull-down MOSFET.

9. The MOSFET device of claim 3 wherein the resistor is substantially 100 to 10,000 ohms.

10. The MOSFET device of claim 4 wherein the pull-down MOSFET and the capacitor and resistor are formed on a die separate from and smaller than a die on which the main power MOSFET is formed, the two die being electrically connected at the source, drain and gate electrodes of the main power MOSFET and placed within a single package.

11. The MOSFET device of claim 4 wherein the main power MOSFET, the pull-down MOSFET, the capacitor and the resistor are formed on a single die.

12. The MOSFET device of claim 11 wherein the main power MOSFET and the pull-down MOSFET are power MOSFETs with vertical current flow which are formed in source down configuration.

13. The MOSFET device of claim 11 further comprising a low-side switch in a push-pull stage of a switching converter with integrated main power MOSFET and pull-down MOSFET.

14. The MOSFET device of claim 12 further comprising a low-side switch in a push-pull stage of a switching converter with integrated main power MOSFET and pull-down MOSFET.

15. The MOSFET device of claim 11 further comprising a high-side switch in a push-pull stage of a switching converter with integrated main power MOSFET and pull-down MOSFET.

16. The MOSFET device of claim 12 further comprising a high-side switch in a push-pull stage of a switching converter with integrated main power MOSFET and pull-down MOSFET.

17. A switching DC to DC converter having a high-side switch and a low-side switch, the low-side switch comprising:
a main power MOSFET having a drain, source and gate;
a pull-down MOSFET having a drain connected to the gate of the main power MOSFET and a source connected to the source of the main power MOSFET, a gate of the pull-down MOSFET being connected to one terminal of a capacitor, another terminal of the capacitor being connected to the drain of the main power MOSFET, whereby dv/dt of a voltage bias at the drain of the main power MOSFET during turn-off of the main power MOSFET causes the pull-down MOSFET to turn-on and hold the gate of the main power MOSFET at or near source potential to prevent turn-on of the main power MOSFET during turn-off.

18. The switching converter of claim 17 wherein the pull-down MOSFET has an active area of substantially 0.5 to 4.0 percent of the active area of the main power MOSFET.

19. The switching converter of claim 17 further comprising a resistor connected between the gate of the pull-down MOSFET and the source thereof.

20. The switching converter of claim 19 wherein the resistor value is substantially 100 to 10,000 ohms.

21. The switching converter of claim 20 wherein the capacitor has a value of substantially 50 and 150 percent of the Cgs of the pull-down MOSFET.

22. The switching converter of claim 17 having a high-side switch comprising:
a main power MOSFET having a drain, source and gate;
a pull-down MOSFET having a drain connected to the gate of the main power MOSFET and a source connected to the source of the main power MOSFET, a gate of the pull-down MOSFET being connected to one terminal of a capacitor, another terminal of the capacitor being connected to the drain of the main power MOSFET, whereby dv/dt of a voltage bias at the drain of the main power MOSFET during turn-off of the main power MOSFET causes the pull-down MOSFET to turn-on and hold the gate of the main power MOSFET at or near source potential to prevent turn-on of the main power MOSFET during turn-off.

23. A method of operating a switching DC to DC converter comprising:
alternating turning on and off a high-side MOSFET switch and a low-side MOSFET switch;
when turning the low-side MOSFET switch off, utilizing capacitive coupling between a drain of the low-side switch and a gate of a pull-down MOSFET to turn-on the pull-down MOSFET, and to couple a gate of the low-side MOSFET switch to a source thereof, whereby conduction in the low-side MOSFET switch during turn-off is reduced or prevented.
